(19) United States
(12) Patent Application Publication
(10) Pub. No.: US 2024/0407240 A1
(43) Pub. Date: Dec. 5, 2024

(54) DISPLAY PAENL AND DISPLAY DEVICE

(71) Applicants: MIANYANG HKC OPTOELECTRONICS TECHNOLOGY CO., LTD., Mianyang (CN); HKC CORPORATION LIMITED, Baoan District (CN)

(72) Inventors: Rong LI, Mianyang (CN); Lidan YE, Mianyang (CN)

(21) Appl. No.: 18/668,291

(22) Filed: May 20, 2024

(30) Foreign Application Priority Data
May 31, 2023 (CN) 202310636191.X

(51) Int. Cl. H10K 59/80

(52) U.S. Cl. CPC H10K 59/8792

(57) ABSTRACT

A display panel and a display device are provided. The display panel includes a color film substrate. The color film substrate includes multiple color resist units. The privacy film includes multiple privacy units disposed corresponding to the multiple color resist units. Each privacy unit has a transparent film and multiple charged particles. When the privacy film is in a first state, the multiple charged particles are attached to one end of the transparent film close to the corresponding color resist unit and exceed a surface of the corresponding color resist unit by a first height. When the privacy film is in a second state, the multiple charged particles are attached to one end of the transparent film close to the corresponding color resist unit and exceed the surface of the corresponding color resist unit by a second height, and the second height is greater than the first height.

### CROSS-REFERENCE TO RELATED APPLICATIONS

This application claims priority under 35 U.S.C. § 119 (a) to Chinese Patent Application No. 202310636191.X, filed May 31, 2023, the entire disclosure of which is incorporated herein by reference.

### TECHNICAL FIELD

This disclosure relates to the field of display technology, and in particular to a display panel and a display device.

### BACKGROUND

With continuous development of the display industry and widespread application of display panels, requirements of users for multi-functionalization of the display panels are also increasing. For example, with increasing attention of the user to privacy, in a public scenario or some special scenarios, when the user uses a display product such as a mobile phone, a tablet computer, or a notebook computer, the user may need the display product to implement a privacy function to protect privacy.

However, if a display effect of the display panel is limited to a privacy state, and intelligent adjustment of a display view angle cannot be satisfied, a viewing experience of the user will also be reduced to a large extent when switching usage scenarios.

### SUMMARY

In a first aspect, a display panel having a light-exiting surface is provided in the present disclosure. The display panel includes a color film substrate and a privacy film. The color film substrate includes a carrier plate and multiple color resist units. The carrier plate has a first surface and a second surface opposite to the first surface, the first surface is closer to the light-exiting surface than the second surface, and the multiple color resist units are arranged at intervals on the carrier plate and are away from the first surface. The privacy film includes multiple privacy units. The multiple privacy units are disposed corresponding to the multiple color resist units and different privacy units correspond to different color resist units. Each of the multiple privacy units has a transparent film and multiple charged particles, the transparent film covers a corresponding color resist unit and part of the transparent film is located in at least part of a gap between two adjacent color resist units, the transparent film defines a cavity, and the multiple charged particles are accommodated in the cavity. The privacy film has a first state and a second state. When the privacy film is in the first state, the multiple charged particles in the privacy unit are attached to one end of the transparent film close to the corresponding color resist unit and exceed a surface of the corresponding color resist unit by a first height. When the privacy film is in the second state, the multiple charged particles in the privacy unit are attached to said one end of the transparent film close to the corresponding color resist unit and exceed the surface of the corresponding color resist unit by a second height, and the second height is greater than the first height. When the privacy film is in the first state or the second state, at least part of each of the multiple charged particles is disposed in the gap between the two adjacent color resist units.

In a second aspect, a display device is further provided in the present disclosure. The display device includes a housing and a display panel. The housing is configured to accommodate the display panel. The display panel has a light-exiting surface. The display panel includes a color film substrate and a privacy film. The color film substrate includes a carrier plate and multiple color resist units. The carrier plate has a first surface and a second surface opposite to the first surface, the first surface is closer to the light-exiting surface than the second surface, and the multiple color resist units are arranged at intervals on the carrier plate and are away from the first surface. The privacy film includes multiple privacy units. The multiple privacy units are disposed corresponding to the multiple color resist units and different privacy units correspond to different color resist units. Each of the multiple privacy units has a transparent film and multiple charged particles, the transparent film covers a corresponding color resist unit and part of the transparent film is located in at least part of a gap between two adjacent color resist units, the transparent film defines a cavity, and the multiple charged particles are accommodated in the cavity. The privacy film has a first state and a second state. When the privacy film is in the first state, the multiple charged particles in the privacy unit are attached to one end of the transparent film close to the corresponding color resist unit and exceed a surface of the corresponding color resist unit by a first height. When the privacy film is in the second state, the multiple charged particles in the privacy unit are attached to said one end of the transparent film close to the corresponding color resist unit and exceed the surface of the corresponding color resist unit by a second height, and the second height is greater than the first height. When the privacy film is in the first state or the second state, at least part of each of the multiple charged particles is disposed in the gap between the two adjacent color resist units.

### BRIEF DESCRIPTION OF THE DRAWINGS

To explain technical solutions in implementations of the present disclosure or the related art more clearly, the following will give a brief introduction to accompanying drawings which are needed to be used in description of implementations or the related art. Apparently, the accompanying drawings in the following description are some implementations of the present disclosure. For those of ordinary skill in the art, other accompanying drawings can be obtained according to these accompanying drawings without creative efforts.

FIG. 1 is a schematic structural diagram of a display device and a display panel in an embodiment of the present disclosure.

FIG. 2 is a schematic cross-sectional structural diagram of the display panel provided in FIG. 1 in a second state, taken along line A-A.

FIG. 3 is a schematic cross-sectional structural diagram of the display panel provided in FIG. 1 in a first state, taken along line A-A.

FIG. 4 is a schematic structural diagram of a privacy unit in a second state in an embodiment of the present disclosure.

FIG. 5 is a schematic structural diagram of a privacy unit in a first state in an embodiment of the present disclosure.

FIG. 6 is a schematic diagram of a light path of a display panel in a second state in an embodiment of the present disclosure.

FIG. 7 is a schematic diagram of a light path of a display panel in a first state in an embodiment of the present disclosure.

FIG. 8 is a schematic cross-sectional structural diagram of a display panel taken along line A-A in one embodiment of the present disclosure.

FIG. 9 is a schematic diagram of a light path of a display panel in another embodiment of the present disclosure.

FIG. 10 is a schematic cross-sectional structural diagram of a display panel taken along line A-A in yet another embodiment of the present disclosure.

FIG. 11 is a schematic cross-sectional structural diagram of a privacy unit in an embodiment of the present disclosure.

FIG. 12 is a schematic cross-sectional structural diagram of multiple privacy units and multiple color resist units in an embodiment of the present disclosure.

FIG. 13 is a schematic structural diagram of a top view of a display panel in an embodiment of the present disclosure.

FIG. 14 is a schematic cross-sectional structural diagram of a privacy unit and a color resist unit in yet another embodiment of the present disclosure.

FIG. 15 is a schematic cross-sectional structural diagram of a display panel taken along line A-A in a second state in yet another embodiment of the present disclosure.

FIG. 16 is a schematic cross-sectional structural diagram of a display panel taken along line A-A in a first state in yet another embodiment of the present disclosure.

### DETAILED DESCRIPTION

Technical solutions of implementations of the present disclosure will be described clearly and completely with reference to accompanying drawings in implementations of the present disclosure. Apparently, implementations described herein are merely some implementations, rather than all implementations, of the present disclosure. Based on implementations of the present disclosure, all other implementations obtained by those of ordinary skill in the art without creative effort shall fall within the protection scope of the present disclosure.

Terms “first”, “second”, and the like used in the specification, the claims, and the accompany drawings of the present disclosure are used to distinguish different objects rather than describe a particular order. In addition, the terms “include”, “include”, and “have” as well as variations thereof are intended to cover non-exclusive inclusion. For example, a process, a method, a system, a product, or a device including a series of operations or units is not limited to the listed operations or units, it can optionally include other operations or units that are not listed; alternatively, other operations or units inherent to the process, the method, the product, or the device can be included either.

A term “embodiment” or “implementation” referred to herein means that a particular feature, structure, or characteristic described in conjunction with embodiments or implementations may be contained in at least one embodiment of the present disclosure. The phrase appearing in various places in the specification does not necessarily refer to the same embodiment, nor does it refer an independent or alternative embodiment that is mutually exclusive with other embodiments. It is expressly and implicitly understood by those skilled in the art that an embodiment described herein may be combined with other embodiments.

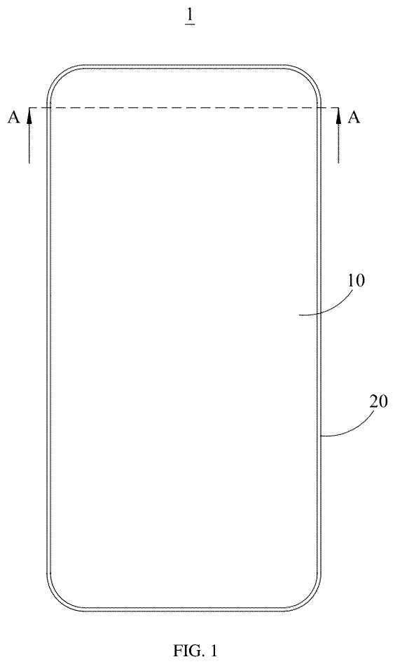

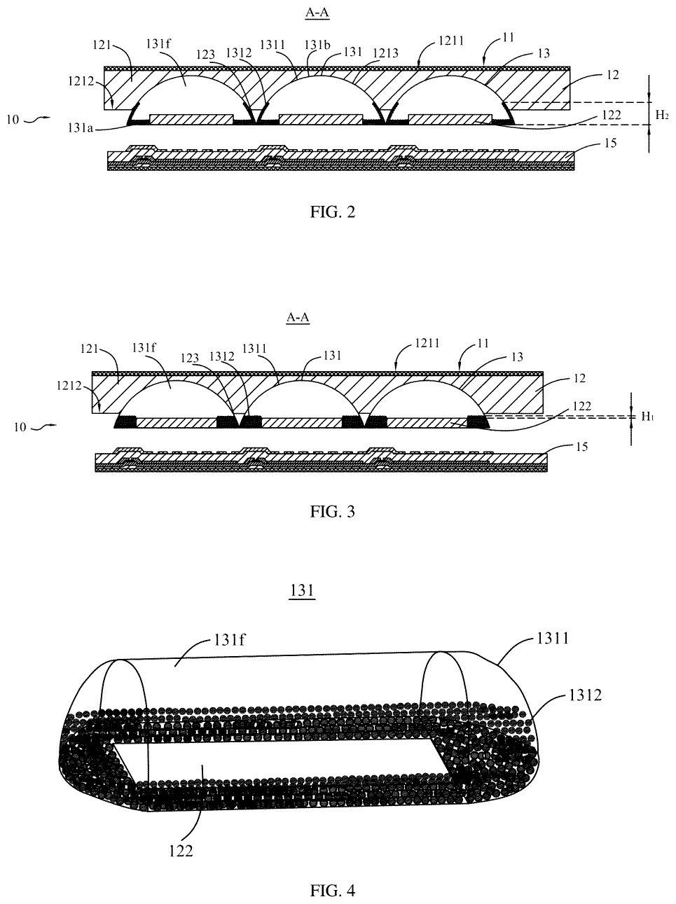

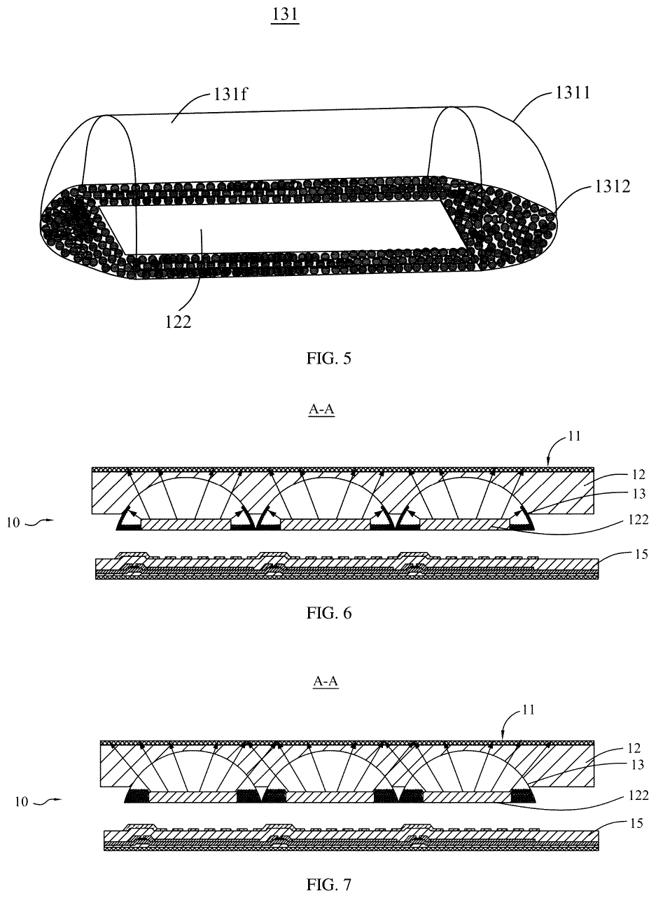

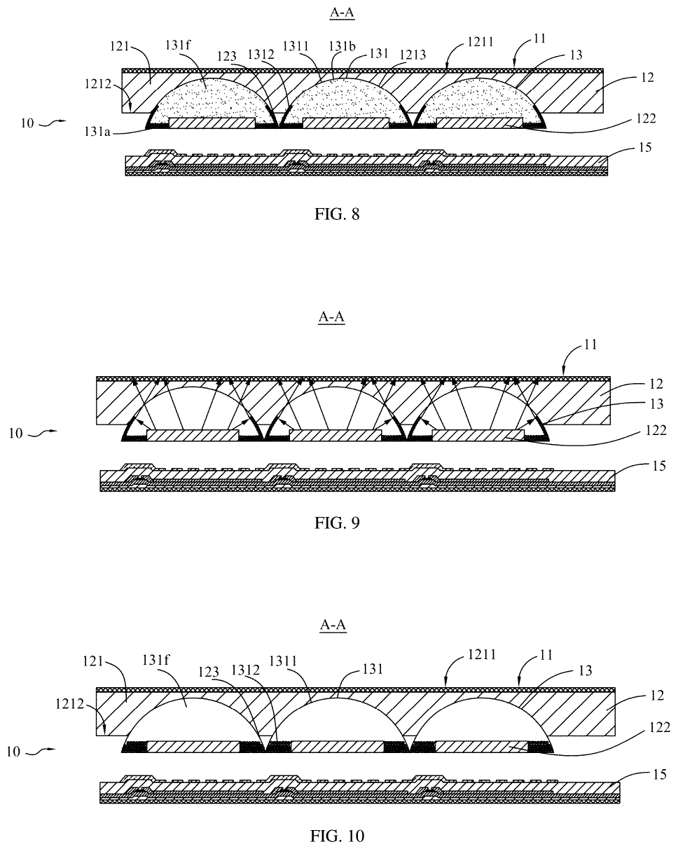

Reference can be made to FIG. 1 to FIG. 10, where FIG. 1 is a schematic structural diagram of a display device and a display panel in an embodiment of the present disclosure, FIG. 2 is a schematic cross-sectional structural diagram of the display panel provided in FIG. 1 in a second state, taken along line A-A, FIG. 3 is a schematic cross-sectional structural diagram of the display panel provided in FIG. 1 in a first state, taken along line A-A, FIG. 4 is a schematic structural diagram of a privacy unit in a second state in an embodiment of the present disclosure, FIG. 5 is a schematic structural diagram of a privacy unit in a first state in an embodiment of the present disclosure, FIG. 6 is a schematic diagram of a light path of a display panel in a second state in an embodiment of the present disclosure, FIG. 7 is a schematic diagram of a light path of a display panel in a first state in an embodiment of the present disclosure, FIG. 8 is a schematic cross-sectional structural diagram of a display panel taken along line A-A in one embodiment of the present disclosure, FIG. 9 is a schematic diagram of a light path of a display panel in another embodiment of the present disclosure, and FIG. 10 is a schematic cross-sectional structural diagram of a display panel taken along line A-A in yet another embodiment of the present disclosure. A display panel 10 is provided in an embodiment of the present disclosure. The display panel 10 has a light-exiting surface 11. The display panel 10 includes a color film substrate 12 and a privacy film 13. The color film substrate 12 includes a carrier plate 121 and multiple color resist units 122. The carrier plate 121 has a first surface 1211 and a second surface 1212 opposite to the first surface 1211. The first surface 1211 is closer to the light-exiting surface 11 than the second surface 1212. The multiple color resist units 122 are arranged at intervals on the carrier plate 121 and are away from the first surface 1211. The privacy film 13 includes multiple privacy units 131 disposed corresponding to the multiple color resist units 122. Different privacy units 131 correspond to different color resist units 122. Each of the multiple privacy units 131 has a transparent film 1311 and multiple charged particles 1312. The transparent film 1311 covers a corresponding color resist unit 122 and part of the transparent film 1311 is located in at least part of a gap 123 between two adjacent color resist units 122. The transparent film 1311 defines a cavity 131f, and the multiple charged particles 1312 are accommodated in the cavity 131f. The privacy film 13 has a first state and a second state. When the privacy film 13 is in the first state, the multiple charged particles 1312 in the privacy unit 131 are attached to one end of the transparent film 1311 close to the corresponding color resist unit 122 and exceed a surface of the corresponding color resist unit 122 by a first height H1. When the privacy film 13 is in the second state, the multiple charged particles 1312 in the privacy unit 131 are attached to said one end of the transparent film 1311 close to the corresponding color resist unit 122 and exceed the surface of the corresponding color resist units 122 by a second height H2, and the second height H2 is greater than the first height H1. When the privacy film 13 is in the first state or the second state, at least part of each of the multiple charged particles 1312 is disposed in the gap 123 between the two adjacent color resist units 122.

The display panel 10 may be, but is not limited to, a Liquid Crystal (LC) display panel, an Organic Light-Emitting Diode (OLED) display panel, a field emission display panel, a plasma display panel, a curved panel, or the like. The OLED display panel may further include a polarizer-less (i.e., Color On Encapsulation, COE) panel. It can be understood that the function type of the display panel 10 shall not be construed as a limitation to the display panel 10 provided in this implementation.

The image display can be performed on the light-exiting surface 11 in the display panel 10. The color film substrate 12 can perform color filtering on the light emitted from the display panel 10 and greatly improve the color performance of the display panel 10.

The material of the carrier plate 121 may be, but is not limited to, glass, a transparent organic layer, or other materials. The carrier plate 121 has a first surface 1211 and a second surface 1212 opposite to the first surface 1211. The first surface 1211 is closer to the light-exiting surface 11 than the second surface 1212, and in other words, the first surface 1211 is close to the light-exiting surface 11, and the first surface 1211 may, but is not limited to, directly face the light-exiting surface 11.

Optionally, the color resist unit 122 may be a Red (R) color resist, a Green (G) color resist, a Blue (B) color resist, or color resists of other colors. The multiple color resist units 122 may include color resists of multiple colors, which is not limited in the present disclosure.

The multiple color resist units 122 are arranged at intervals on the carrier plate 121 and are away from the first surface 1211, and are configured to filter the light of the display panel 10.

Optionally, the number of color resist units 122 may be two, three, four, or other number. A distance between two adjacent color resist units 122 may be equal or unequal. The multiple color resist units 122 may be, but are not limited to, arranged in an array on the carrier plate 121.

Optionally, the color resist unit 122 may be directly disposed on the carrier plate 121 or be indirectly disposed on the carrier plate 121. In the schematic diagram of this implementation, for example, the color resist unit 122 is indirectly disposed on the carrier plate 121 through the privacy film 13.

Optionally, the number of privacy units 131 may be, but is not limited to, two, three, four, or other number. Two adjacent privacy units 131 may, but are not limited to, be spaced apart from or abut against each other. In the schematic diagram of this implementation, for example, the two adjacent privacy units 131 abut against each other.

Optionally, the multiple privacy units 131 may be arranged in an array on the carrier plate 121, and the number of privacy units 131 may be equal to the number of color resist units 122.

The privacy film 13 may be disposed on the second surface 1212 of the carrier plate 121. Specifically, the second surface 1212 may be a flat surface, or the second surface 1212 may define a recess 1213 recessed towards the light-exiting surface 11 of the display panel 10. The privacy unit 131 may have one end accommodated in the recess 1213, and the other end carrying the color resist unit 122. According to the display panel 10 provided in this implementation, the privacy film 13 is disposed on the carrier plate 121, and compared to traditional designs of a privacy assembly on the display panel alone, due to the structure of the privacy film 13 provided in this implementation, the display panel 10 has a privacy function, and the thickness of the display panel 10 is also increased as small as possible or is not additionally increased, so that the display panel 10 can meet the design requirements of lightness and thinness.

The multiple privacy units 131 are disposed corresponding to the multiple color resist units 122, and different privacy units 131 correspond to different color resist units 122. Specifically, the privacy unit 131 may be disposed at one side of the color resist unit 122 close to the light-exiting surface 11, and the privacy unit 131 may cover a surface of the color resist units 122 close to the light-exiting surface 11.

The privacy unit 131 may be, but is not limited to, designed to have a structure similar to a capsule. The privacy unit 131 has a transparent film 1311 and multiple charged particles 1312.

Optionally, the transparent film 1311 may be made of a colloid or other composite materials. When the transparent film 1311 is made of a colloid, such as, a gelatin, a silica sol, or a gum, the transparent film 1311 can meet requirements of mechanical strength and flexibility at the same time, and can be used for a flexible display panel 10.

The transparent film 1311 cooperatively define the cavity 131f, and the multiple charged particles 1312 may be accommodated in the cavity 1. Optionally, the shape of the cavity 131f may be a cylinder, or an approximate cylinder, a cube, or other shapes.

Optionally, in an implementation of the present disclosure (FIG. 8), the cavity 131f of the transparent film 1311 may also be filled with a transparent liquid, thereby facilitating the movement of the multiple charged particles 1312.

The charged particle 1312 may be made of carbon black or other dark materials, and charges are adsorbed by the charged particle 1312 through modification or other processes. When the light in the display panel 10 irradiates the charged particle 1312, the charged particle 1312 may, but is not limited to, block or reduce the passage of the light through adsorption or reflection.

Further, in other implementations of the present disclosure (FIG. 9), a surface of the charged particle 1312 may also be coated with a reflective coating for reflecting light, thereby reducing the loss of light emitted from the color resist units, so that the display panel has the privacy function, and it is ensured that optical efficiency of the display panel is not reduced, thereby improving the display yield of the display panel.

The transparent film 1311 covers the color resist unit 122. Specifically, the transparent film 1311 may cover a surface of the color resist unit 122 close to the light-exiting surface 11, and the transparent film 1311 may also partially or completely cover a peripheral side surface of the color resist unit 122.

Part of the transparent film 1311 is located in at least part of the gap 123 between two adjacent color resist units 122, and the transparent film 1311 may be disposed around the peripheral side surface of the color resist unit 122, so that the charged particles 1312 in the cavity 131f can also be distributed in the gap 123, and the charged particles 1312 can be disposed around the peripheral side surface of the color resist unit 122. On one hand, when privacy is not necessary for the display panel 10, the charged particles 1312 can be accommodated in the gap 123 between the two adjacent color resist units 122, thereby not affecting the normal light-exiting of the color resist units 122, so that the display panel 10 has multiple function states, such as a privacy state, a non-privacy state, etc. On the other hand, since the charged particles 1312 each have a function of blocking light transmission, the charged particles 1312 can be densely distributed in the gap 123 between the two adjacent color resist units 122, thereby replacing a black matrix in the display panel 10 and simplifying the technological manufacturing process of the display panel 10.

Optionally, the privacy unit 131 may be provided with an electrode 1315. When the electrode 1315 is loaded with an electrical signal, the charged particles 1312 will move in the cavity 131f under the attraction of the electrode 1315, and the charged particles 1312 may have different distribution states in the cavity 131f according to different cases in which the electrode 1315 is loaded with the electrical signal.

When the charged particles 1312 have different distribution states in the cavity 131f, the privacy film 13 and the display panel 10 may also have different viewing angle states. Specifically, the privacy film 13 may, but is not limited to, have a first state and a second state, where the first state may be a sharing state, and the second state may be a privacy state.

When the privacy film 13 is in the first state, that is, when the display panel 10 is in the sharing state, the multiple charged particles 1312 in the privacy unit 131 are attached to one end of the transparent film 1311 close to the color resist unit 122 and exceed the surface of the color resist unit 122 by a first height H1. Specifically, the first height H1 may be, but is not limited to, a maximum value among distances between surfaces of the charged particle 1312 and a plane on which the surface of the color resist unit 122 close to the light-exiting surface 11 is located.

When the privacy film 13 is in the second state, that is, when the display panel 10 is in the privacy state, the multiple charged particles 1312 in the privacy unit 131 are attached to one end of the transparent film 1311 close to the color resist unit 122 and exceed the surface of the color resist unit 122 by a second height H2. Specifically, the second height H2 may be, but is not limited to, a maximum value among distances between surfaces of the charged particles 1312 and the plane on which the surface of the color resist unit 122 close to the light-exiting surface 11 is located.

It can be understood that the first height H1 and the second height H2 each are a height defined by the multiple charged particles 1312 together, and are not a height of a single charged particle 1312.

The second height H2 is greater than the first height H1, so that when the privacy film 13 is in the second state, part of the light emitted from the color resist unit 122 to the light-exiting surface 11 is blocked by the charged particles 1312, so that an angle at which the light is emitted to the light-exiting surface 11 is limited, and a viewing angle of the display panel 10 is narrowed. Therefore, images on the display panel 10 can be normally viewed from a front viewing angle, but cannot be normally viewed from a side viewing angle, so that the display panel 10 is in the privacy state.

However, when the privacy film 13 is in the first state, the light emitted from the color resist unit 122 to the light-exiting surface 11 may not be blocked by the charged particles 1312, or compared to the privacy film 13 being in the second state, the light emitted from the color resist unit 122 to the light-exiting surface 11 may be less blocked by the charged particles 1312, so that compared to the privacy film 13 being the second state, the angle at which the light is emitted to the light-exiting surface 11 is increased, and the viewing angle of the display panel 10 is increased.

Further, in an implementation (FIG. 10) of the present disclosure, when the light emitted from the color resist unit 122 to the light-exiting surface 11 is not blocked by the charged particles 1312, that is, when no charged particle 1312 exceed the surface of the color resist unit 122 close to the light-exiting surface 11, the images on the display panel 10 can be normally viewed from various viewing angles, so that the display panel 10 is in a normal display state.

Further, when the privacy film 13 is in the first state or the second state, at least part of each of the multiple charged particles 1312 is at least partially disposed in the gap 123 between the two adjacent color resist units 122, so that a design of a black matrix in a traditional display panel can be replaced, or a black matrix can be completely replaced, thereby simplifying the manufacturing process of the display panel 10.

To sum up, the display panel 10 provided in this implementation includes the color film substrate 12 and the privacy film 13. The color film substrate 12 includes the carrier plate 121 and the multiple color resist units 122. The privacy film 13 includes multiple privacy units 131, and the multiple privacy units 131 are disposed corresponding to the multiple color resist units 122. In other words, the privacy film 13 is disposed in the color film substrate 12, and compared to the traditional designs of the privacy assembly on the display panel alone, the privacy film 13 does not increase the thickness of the display panel 10 additionally, so that the display panel 10 is designed to be light and thin. In addition, the privacy film 13 has the first state and the second state. When the privacy film 13 is in the first state, the multiple charged particles 1312 in the privacy unit 131 are attached to one end of the transparent film 1311 close to the color resist unit 122 and exceed the surface of the color resist unit 122 by the first height H1. When the privacy film 13 is in the second state, the multiple charged particles 1312 in the privacy unit 131 are attached to one end of the transparent film 1311 close to the color resist unit 122 and exceed the surface of the color resist units 122 by the second height H2, and the second height H2 is greater than the first height H1, so that the display panel 10 has different display viewing angles, and with adjustment of distribution states of the multiple charged particles 1312, the display panel 10 can have a full-viewing-angle display state, and the display panel 10 can flexibly switch between the privacy state and the normal display state. Furthermore, the multiple charged particles 1312 are at least partially disposed in the gap 123 between the two color resist units 122, so that the design of the black matrix in the traditional display panel can be replaced with the aid of the multiple charge particles 1312, thereby simplifying the technological manufacturing process of the display panel 10.

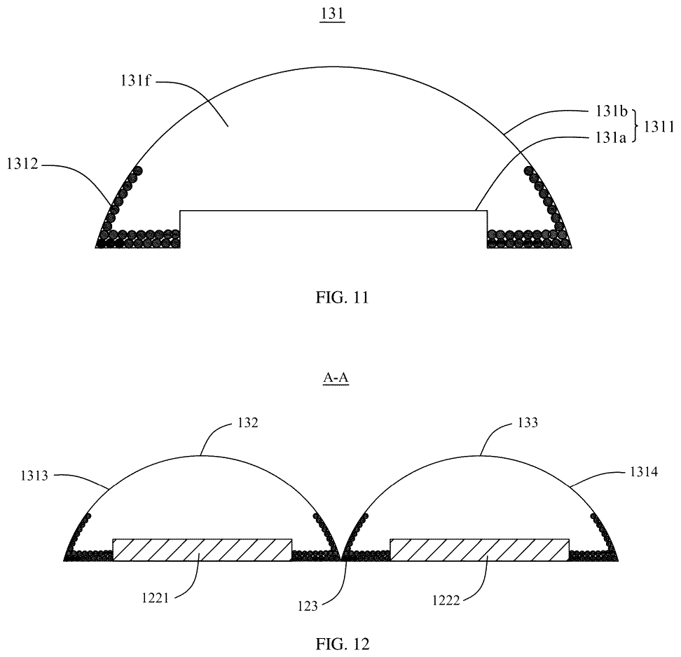

Reference can be made to FIG. 2, FIG. 11, and FIG. 14, where FIG. 11 is a schematic cross-sectional structural diagram of a privacy unit in an embodiment of the present disclosure, and FIG. 14 is a schematic cross-sectional structural diagram of a privacy unit and a color resist unit in yet another embodiment of the present disclosure. The transparent film 1311 includes a first film-portion 131a and a second film-portion 131b. The first film-portion 131a is attached to the surface of the color resist unit 122 close to the light-exiting surface 11. The second film-portion 131b and a peripheral edge of the first film-portion 131a are connected in a bent manner and collectively define the cavity 131f. The second film-portion 131b is farther away from the color resist unit 122 than the first film-portion 131a.

Optionally, the first film-portion 131a may be partially attached to the surface of the color resist units 122 close to the light-exiting surface 11, and partially attached to the peripheral side surface of the color resist unit 122. On one hand, the first film-portion 131a can carry the color resist unit 122, and on the other hand, the charged particles 1312 accommodated in the transparent film 1311 can be disposed around the peripheral side of the color resist unit 122, thereby realizing a comprehensive effect of privacy and anti-light leakage.

The second film-portion 131b is connected to a peripheral edge of the first film-portion 131a away from the color resist unit 122 in a bent manner. Specifically, a peripheral edge of the second film-portion 131b may be, but is not limited to, connected to the peripheral edge of the first film-portion 131a in a bent manner, so that the second film-portion 131b and the first film-portion 131a cooperatively define the cavity 131f.

The second film-portion 131b is farther away from the color resist unit 122 than the first film-portion 131a, and the second film-portion 131b may be, but is not limited to, disposed in or partially disposed in the carrier plate 121.

Optionally, the surface of the second film-portion 131b may be a flat surface (FIG. 14), a curved surface, or the like, and the surface of the first film-portion 131a may be formed by several sub-surfaces connected to one another in a bent manner, so as to be attached to the peripheral side surface of the color resist unit 122.

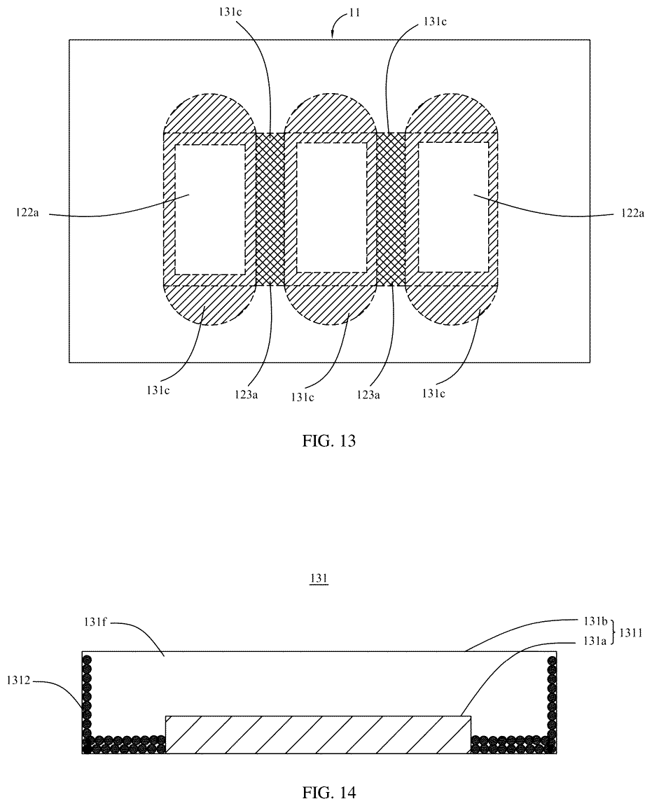

Reference can be made to FIG. 2 and FIG. 12, where FIG. 12 is a schematic cross-sectional structural diagram of multiple privacy units and multiple color resist units in an embodiment of the present disclosure. The gap 123 is defined between the two adjacent color resist units 122, and a transparent film 1311 in one of two adjacent privacy units 131 is located in part of the gap 123. A transparent film 1311 in the other one of the two adjacent privacy units 131 is located in the other part of the gap 123 and abuts against the transparent film 1311 in said one of the two adjacent privacy units 131.

Specifically, the multiple color resist units 122 may at least include a first color-resist-unit 1221 and a second color-resist-unit 1222, and the multiple privacy films 13 may also at least include a first privacy-film 132 and a second privacy-film 133. The first privacy-film 132 is disposed corresponding to the first color-resist-unit 1221, that is, the first privacy-film 132 is disposed at one side of the first color-resist-unit 1221 close to the light-exiting surface 11. The second privacy-film 133 is disposed corresponding to the second color-resist-unit 1222, that is, the second privacy-film 133 is disposed at one side of the second color-resist-unit 1222 close to the light-exiting surface 11. The first privacy-film 132 may have a first transparent film 1313, and the first transparent film 1313 is disposed in part of the gap 123. The second privacy-film 133 may have a second transparent film 1314, and the second transparent film 1314 is disposed in the other part of the gap 123. In addition, the first transparent film 1313 may partially abut against the second transparent film 1314, so that multiple charged particles 1312 filled in the first privacy-film 132 and multiple charged particles 1312 filled in the second privacy-film 133 can block the gap 123, and prevent light leakage and color mixing of light between the first color-resist-unit 1221 and the second color-resist-unit 1222, thereby ensuring that the display panel 10 has excellent display taste.

It should be noted that the gap 123 may or may not be completely filled with the first privacy-film 132 and the second privacy-film 133, which is not limited in the present disclosure.

Optionally, the surface of the first privacy-film 132 close to the first color-resist-unit 1221 and the surface of the second privacy-film 133 close to the second color-resist-units 1222 may be in the same horizontal plane or different horizontal planes. In other words, in other implementations of the present disclosure, a position of the first privacy-film 132 and a position of the second privacy-film 133 can also be adjusted according to the volume of the first color-resist-unit 1221 being different from the volume of the second color-resist-unit 1222, as long as the first privacy-film 132 abuts against the second privacy-film 133.

Reference can be made to FIG. 2 and FIG. 13, where FIG. 13 is a schematic structural diagram of a top view of a display panel in an embodiment of the present disclosure. The multiple charged particles 1312 are filled in the gap 123, the gap 123 has a first orthographic projection 123a on the light-exiting surface 11, the multiple charged particles 1312 have a second orthographic projection 131c on the light-exiting surface 11, and the second orthographic projection 131c at least partially covers the first orthographic projection 123a.

Specifically, when the privacy film 13 is in the first state or when the privacy film 13 is in the second state, the multiple charged particles 1312 are all filled in the gap 123 under the adsorption effect of the electrode 1315. The first orthographic projection 123a is an orthographic projection range of the gap 123 on the light-exiting surface 11, the second orthographic projection 131c is an orthographic projection range of the multiple charged particles 1312 on the light-exiting surface 11, and the second orthographic projection 131c may, but is not limited to, cover or partially cover the first orthographic projection 123a.

In an embodiment, the second orthographic projection 131c covers the first orthographic projection 123a, so that the multiple charged particles 1312 can prevent the light leakage between the gap 123. Therefore, the design of the black matrix in the traditional display panel can be replaced with the aid of the multiple charged particles 1312, so that the display panel 10 has the privacy function, and the technological process of the display panel 10 can be simplified, thereby reducing the manufacturing cost of the display panel 10.

Referring to FIG. 2 and FIG. 13 again, the color resist unit 122 have a third orthographic projection 122a on the light-exiting surface 11, and the third orthographic projection 122a abuts against the second orthographic projection 131c, but overlaps no second orthographic projection 131c.

Specifically, the third orthographic projection 122a is an orthographic projection range of the color resist unit 122 on the light-exiting surface 11. The peripheral edge of the third orthographic projection 122a may, but is not limited to, abut against or substantially abut against the second orthographic projection 131c, and the third orthographic projection 122a and the second orthographic projection 131c do not overlap with each other, so that the multiple charged particles 1312 have the privacy function and replace the black matrix, and do not affect a normal light-exiting effect of the color resist unit 122, thereby ensuring the optical display effect of the display panel 10.

It should be noted that in some implementations of the present disclosure, the display panel 10 may, but is not limited to, control the magnitude of the electrical signal loaded on the electrode 1315 or use other adjustment manners to control the movement track of the multiple charged particles 1312 and distribution positions of the multiple charged particles 1312 stagnated, so as not to affect the light-exiting effect of the surface of the color resist units 122 directly opposite to the light-exiting surface 11. In addition, since the charged particles 1312 each have a bistable effect (a magnetic hysteresis effect) in the privacy unit 131, when the charged particles 1312 keep at fixed positions in the display panel 10, too much energy consumption will not be generated in the display panel 10, and the display panel 10 can also balance the performance experience of energy conservation and low power consumption.

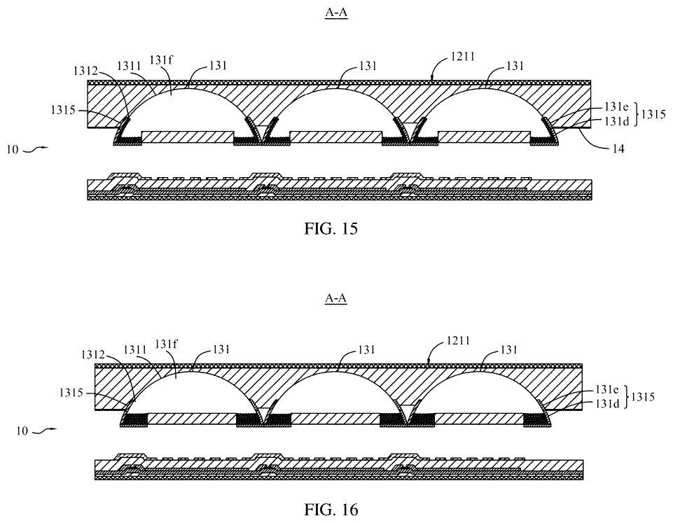

Reference can be made to FIG. 15, where FIG. 15 is a schematic cross-sectional structural diagram of a display panel taken along line A-A in a second state in yet another embodiment of the present disclosure. The privacy unit 131 further includes an electrode 1315. The electrode 1315 is disposed at one side of the transparent film 1311 away from the cavity 1311. When the electrode 1315 is loaded with an electrical signal, the electrode 1315 adsorbs the charged particles 1312.

Specifically, the electrode 1315 is disposed at one side of the transparent film 1311 away from the cavity 1311, and the electrode 1315 may be, but is not limited to, attached to the transparent film 1311. A surface of the charged particle 1312 may, but is not limited to, carry positive (“+”) charges. When the electrode 1315 is loaded with the electrical signal, the electrode 1315 will attract the charged particles 1312 to positions of the transparent film 1311 close to the electrode 1315, that is, the charged particles 1312 are adsorbed.

The electrode 1315 may be, but is not limited to, loaded with different electrical signals in different segments, so as to control the multiple charged particles 1312 to have different distribution states in the privacy unit 131, so that the display panel 10 has different display viewing angles. Therefore, the display panel 10 can realize flexible privacy from multiple angles, and can also have the normal display state, that is, the display panel 10 has a full-viewing-angle experience.

Optionally, the electrode 1315 may also control the distribution states of the multiple charged particles 1312 by being loaded with electrical signals of different magnitudes or by other implementations.

It can be understood that in other implementations of the present disclosure, the electrode 1315 may also not be attached to the transparent film 1311, as long as it is ensured that an electric field is generated to attract the charged particles 1312 and move the charged particles 1312 to designed positions.

It can be understood that in other implementations of the present disclosure, the charged particles 1312 may also carry other charges, as long as the charged particles are attracted by the electrode 1315, which is not limited in the present disclosure.

The material of the electrode 1315 may be, but is not limited to, Indium Tin Oxides (ITO) or other conductive materials.

In an embodiment, the electrode 1315 is made of a transparent material, so that the electrode 1315 can attract and control the distribution states of the charged particles 1312 in the privacy unit 131, and the normal display viewing angle of the display panel 10 is not affected.

Reference can be made to FIG. 15 and FIG. 16, where FIG. 16 is a schematic cross-sectional structural diagram of a display panel taken along line A-A in a first state in yet another of the present disclosure. The electrode 1315 includes a first electrode-portion 131d and a second electrode-portion 131e. The first electrode-portion 131d is disposed at a peripheral side of a color resist unit 122 corresponding to the privacy unit 131. The second electrode-portion 131e exceeds the color resist unit 122, and the second electrode-portion 131e is closer to the first surface 1211 than the first electrode-portion 131d. The multiple charged particles 1312 carry charges of a first polarity. When the first electrode-portion 131d is loaded with a voltage signal of a second polarity and the second electrode-portion 131e is loaded with a voltage signal of the first polarity, the multiple charged particles 1312 are adsorbed by the first electrode-portion 131d, and the privacy film 13 is in the first state. When the first electrode-portion 131d and the second electrode-portion 131e each are loaded with the voltage signal of the second polarity, the multiple charged particles 1312 are adsorbed by the first electrode-portion 131d and the second electrode-portion 131e, and the privacy film 13 is in the second state.

Specifically, the first electrode-portion 131d is disposed at the peripheral side of the color resist unit 122 corresponding to the privacy unit 131, and the first electrode-portion 131d may be, but is not limited to, disposed around the peripheral side of the color resist unit 122. The second electrode-portion 131e exceed the color resist unit 122, that is, the second electrode-portion 131e is closer to the first surface 1211 of the carrier plate 121 than the first electrode-portion 131d.

Optionally, the first electrode-portion 131d and the second electrode-portion 131e each may be, but are not limited to, formed by processes such as soldering, bonding, or integral molding, which is not limited in the present disclosure.

Optionally, the first electrode-portion 131d may be, but is not limited to, a portion disposed only on the peripheral side surface of the corresponding color resist unit 122. Optionally, the first electrode-portion 131d may also be partially attached to the first film-portion 131a, that is, the first electrode-portion 131d may, but is not limited to, include two portions that are connected to each other in a bent manner, where one portion of the first electrode-portion 131d is attached to the first film-portion 131a and is accommodated in the gap 123 between the two adjacent color resist units 122, and the other portion of the first electrode-portion 131d is attached to the second film-portion 131b and is accommodated in the gap 123 between the two adjacent color resist units 122.

In an implementation of the present disclosure, the multiple charged particles 1312 may carry charges of the first polarity, and when the second electrode-portion 131e is loaded with the voltage signal of the first polarity, the second electrode-portion 131e repels the multiple charged particles 1312 due to the principle of like poles repulsion, so that the multiple charged particles 1312 do not stay at positions close to the second electrode-portion 131e. At the same time, the first electrode-portion 131d is loaded with the voltage signal of the second polarity, the first electrode-portion 131d attracts the multiple charged particles 1312, due to the principle of opposite poles attraction, so that the multiple charged particles 1312 are distributed at positions close to the first electrode-portion 131d, that is, distributed at the peripheral side of the color resist unit 122 without exceeding the color resist unit 122. Therefore, the privacy film 13 is in the first state, that is, the display panel 10 is in a shared state with a wide viewing angle.

When the second electrode-portion 131e and the first electrode-portion 131d each are loaded with the voltage signal of the second polarity, the first electrode-portion 131d and the second electrode-portion 131e each attract the multiple charged particles 1312 due to the principle of opposite poles attraction, so that the multiple charged particles 1312 are distributed at positions close to the first electrode-portion 131d and positions close to the second electrode-portion 131e, that is, some of the multiple charged particles 1312 are partially distributed at the peripheral side of the color resist unit 122 and the rest of the multiple charged particles 1312 exceed the color resist unit 122. Therefore, the privacy film 13 is in the second state, that is, the display panel 10 is in a privacy state with a narrow viewing angle.

It can be understood that in another implementation of the present disclosure, the multiple charged particles 1312 may carry charges of the first polarity. When the first electrode-portion 131d is loaded with the voltage signal of the second polarity and the second electrode-portion 131e is not loaded with a voltage signal, the multiple charged particles 1312 may also be distributed at positions close to the first electrode-portion 131d due to the attraction of the first electrode-portion 131d, that is, distributed at the peripheral side of the color resist unit 122 without exceeding the color resist unit 122, so that the privacy film 13 is in the first state, that is, the display panel 10 is in the shared state with the wide viewing angle. However, when the second electrode-portion 131e and the first electrode-portion 131d each are loaded with the voltage signal of the second polarity, the privacy film 13 is in the second state for the similar reason, that is, the display panel 10 is in the privacy state with the narrow view angle.

It can be understood that in yet another implementation of the present disclosure, the multiple charged particles 1312 may carry charges of the first polarity, and the first electrode-portion 131d and the second electrode-portion 131e each are loaded with the voltage signal of the second polarity. When the first electrode-portion 131d and the second electrode-portion 131e each are loaded with a first voltage signal, the privacy film 13 is in the first state. When the first electrode-portion 131d and the second electrode-portion 131e each are loaded with a second voltage signal, the privacy film 13 is in the second state. A signal value of the second voltage signal is greater than a signal value of the first voltage signal. In other words, the privacy film 13 is controlled to be in different states by controlling the magnitude of the voltage signal loaded on the electrode 1315.

It should be noted that the electrode 1315 may further include multiple electrode portions, so that multistage control can be performed by the electrode 1315, and the multiple charged particles 1312 can be controlled to have multiple distribution states by different signals loaded on the electrode portions of different stages.

It can be understood that the electrode 1315 may also be loaded with multiple voltage signals of different magnitudes to control the multiple charged particles 1312 to have multiple distribution states.

For the display panel 10 provided in this implementation of the present disclosure, the privacy film 13 can be flexibly switched between the first state, the second state, or other states by multiple control manners, so that the display panel 10 can realize the privacy state at multiple viewing angles, and can have the normal display effect. Therefore, the display panel 10 can meet multi-scenario user experience and intelligence requirements of the user.

Referring to FIG. 2 again, the carrier plate 121 further defines multiple recesses 1213 corresponding to the multiple privacy units 131, different recesses 1213 correspond to different privacy units 131, and at least part of the privacy unit 131 is accommodated in the corresponding recess 1213.

The number of recesses 1213 may be, but is not limited to, two, three, four, or other number, etc. The number of the recesses 1213 may be, but is not limited to, equal to the number of the anti-peeping units 131.

Further, the recess 1213 is defined at one side of the carrier plate 121 close to the second surface 1212, and the recess 1213 may, but is not limited to, directly face the privacy unit 131. Furthermore, different recesses 1213 directly face different privacy units 131 respectively.

The privacy unit 131 may be, but is not limited to, accommodated in the recess 1213, or partially accommodated in the recess 1213, so that compared to traditional designs of the privacy assembly on the display panel alone, due to the privacy unit 131 provided in this implementation, the display panel 10 has the privacy function, and the thickness of the display panel 10 is also increased as small as possible or is not additionally increased, so that the display panel 10 can meet the design requirements of lightness and thinness.

Further, in an implementation of the present disclosure, the manufacturing process of the recess 1213, the privacy unit 131, and the color resist unit 122 may include the following. step one, manufacture a privacy unit; step two, provide a carrier blank, and define a recess on the carrier blank to obtain a carrier plate; step three, dispose the privacy unit on the carrier plate at a position corresponding to the recess; and step four, coat a color resist unit at one side of the privacy unit away from the carrier plate.

In another implementation of the present disclosure, the manufacturing process of the recess 1213, the privacy unit 131, and the color resist unit 122 may include the following. Step one, provide a carrier blank, and define a recess on the carrier blank to obtain a carrier plate; step two, manufacture a privacy unit in the recess; and step three, coat a color resist unit at one side of the privacy unit away from the carrier plate.

In yet another implementation of the present disclosure, the manufacturing process of the recess 1213, the privacy unit 131, and the color resist unit 122 may include the following. Step one, provide a flexible base; step two, coat a color resist unit on the flexible base; step three, manufacture a privacy unit on a surface of the color resist unit; step four, manufacture a carrier plate on a surface of the privacy unit and a surface of the flexible base; and step five, peel off the flexible base.

It can be understood that the display panel may also be manufactured by other technological processes, and the technological manufacturing process of the display panel should not be a limitation to the display panel in implementations of the present disclosure.

Referring to FIG. 15 again, the display panel 10 further includes a signal line 14. The signal line 14 is disposed on the carrier plate 121, is electrically connected to the electrode 1315, and is configured to load the electrical signal to the electrode 1315.

Optionally, the signal line 14 may be, but is not limited to, partially disposed in the carrier plate 121.

Optionally, one end of the signal line 14 may be electrically connected to the electrode 1315, and the other end of the signal line 14 may be, but is not limited to, electrically connected to an Integrated Circuit (IC) chip of the display panel 10. The IC signal can transmit different control signals to the signal line 14, so that the signal line 14 load different electrical signals to the electrode 1315, thereby controlling different states of the privacy film 13 and realizing the full-viewing-angle display effect of the display panel 10. In other words, when the privacy film 13 is in different states, the light emitted from the light-exiting surface 11 of the display panel 10 has different view angle ranges.

It can be understood that in an implementation of the present disclosure, a user can independently choose a viewing angle range of the display panel 10 based on the requirements, and a privacy degree of the display panel 10 can also be adjusted according to different distribution states of the multiple charged particles 1312, so that the display panel 10 has a wider application range, and the user can have more choices, thereby effectively improving the user experience.

Referring to FIG. 1, FIG. 2, and FIG. 3 again, the display device 1 includes a housing 20 and the display panel 10. The housing 20 is configured to accommodate the display panel 10.

The display device 1 may be, but is not limited to, a device having a display function, which is for a smart phone, a portable phone, a navigation device, a Television (TV), an in-vehicle head unit, a laptop computer, a tablet computer, a Portable Multimedia Player (PMP), a Personal Digital Assistant (PDA), and the like. It can be understood that an application scenario of the display device 1 shall not be a limitation to the display device 1 provided in this implementation.

The material of the housing 20 may be, but is not limited to, a metal, an alloy, a plastic, or another composite material. It can be understood that the material of the housing 20 shall not be a limitation to the display device 1 provided in this implementation. The housing 20 can be configured to accommodate and carry the display panel 10.

The display panel 10 may further include an array substrate 15, and the array substrate 15 may be, but is not limited to, opposite to the color film substrate 12. When the display panel 10 is a LC display panel 10, the array substrate 15 may be provided with a metal electrode 1315 for driving LC molecules. It can be understood that metal electrodes 1315 for driving liquid crystal molecules in a traditional display panel are all disposed on the array substrate 15, and only the signal line 14 and the electrodes 1315 for controlling the privacy units 131 are designed on the color film substrate 12, so that the display panel 10 has a wider application range. It can be understood that the privacy unit 131 may also be for display panels 10 with different types of functions, such as an OLED display panel 10 and the like, which is not limited in the present disclosure.

For the display device 1 provided in this implementation of the present disclosure, the display panel 10 can have a full-viewing-angle display state, that is, the display panel 10 can flexibly switch between the privacy state and the normal display state. In addition, the multiple charged particles 1312 are at least partially disposed in the gap 123 between the two color resist units 122, so that the design of the black matrix in the traditional display panel can be replaced with the aid of the multiple charged particles 1312, thereby simplifying the technological manufacturing process of the display panel 10, and reducing the manufacturing cost of the display panel 10 and the display device 1. Furthermore, when the display device 1 implements the privacy function, there are multiple viewing angles to be chosen, thereby improving the user experience of the display device 1.

The terms of “embodiment” and “implementation” mentioned in the present disclosure means that the specific features, structures, or characteristics described with reference to the embodiments may be encompassed in at least one embodiment of the present disclosure. The phrase at various locations in the specification does not necessarily refer to the same embodiment, or an independent or alternative embodiment exclusive of another embodiment. Those skilled in the art should understand explicitly and implicitly that the embodiments described in the present disclosure may be combined with other embodiments. In addition, it should also be understood that the features, structures or characteristics described in the embodiments of the present disclosure may be combined as desired to obtain embodiments without departing from the spirit and scope of the technical solution of the present disclosure if there is no contradiction between the embodiments.

Finally, it should be noted that the above implementations are merely used for illustrating rather than limiting the technical solutions of the present disclosure; and although the present disclosure has been described in detail with reference to the preferred implementations, those skilled in the art should understand that modifications or equivalent substitutions may be made to the technical solutions of the present disclosure without departing from the spirit and scope of the technical solutions of the present disclosure.

What is claimed is:

1. A display panel having a light-exiting surface and comprising:
a color film substrate comprising a carrier plate and a plurality of color resist units, wherein the carrier plate has a first surface and a second surface opposite to the first surface, the first surface is closer to the light-exiting surface than the second surface, and the plurality of color resist units are arranged at intervals on the carrier plate and are away from the first surface; and
a privacy film comprising a plurality of privacy units, wherein the plurality of privacy units are disposed corresponding to the plurality of color resist units, different privacy units correspond to different color resist units, each of the plurality of privacy units has a transparent film and a plurality of charged particles, the transparent film covers a corresponding color resist unit and part of the transparent film is located in at least part of a gap between two adjacent color resist units, the transparent film defines a cavity, and the plurality of charged particles are accommodated in the cavity; wherein
the privacy film has a first state and a second state, and when the privacy film is in the first state, the plurality of charged particles in the privacy unit are attached to one end of the transparent film close to the corresponding color resist unit and exceed a surface of the corresponding color resist unit by a first height; when the privacy film is in the second state, the plurality of charged particles in the privacy unit are attached to said one end of the transparent film close to the corresponding color resist unit and exceed the surface of the corresponding color resist unit by a second height, and the second height is greater than the first height; and when the privacy film is in the first state or the second state, at least part of each of the plurality of charged particles is disposed in the gap between the two adjacent color resist units.

2. The display panel of claim 1, wherein the transparent film comprises a first film-portion and a second film-portion, the first film-portion is attached to a surface of the corresponding color resist unit close to the light-exiting surface, the second film-portion and a peripheral edge of the first film-portion are connected in a bent manner and cooperatively define the cavity, and the second film-portion is farther away from the corresponding color resist unit than the first film-portion.

3. The display panel of claim 1, wherein the gap is defined between the two adjacent color resist units, and a transparent film in one of two adjacent privacy units is located in part of the gap; and a transparent film in the other one of the two adjacent privacy units is located in the other part of the gap and abuts against the transparent film in said one of the two adjacent privacy units.

4. The display panel of claim 3, wherein the plurality of charged particles are filled in the gap, the gap has a first orthographic projection on the light-exiting surface, the plurality of charged particles have a second orthographic projection on the light-exiting surface, and the second orthographic projection at least partially covers the first orthographic projection.

5. The display panel of claim 4, wherein the two adjacent color resist units each have a third orthographic projection on the light-exiting surface, and the third orthographic projection abuts against the second orthographic projection, but overlaps no second orthographic projection.

6. The display panel of claim 1, wherein the privacy unit further comprises an electrode disposed at one side of the transparent film away from the cavity, and when the electrode is loaded with an electrical signal, the electrode adsorbs the plurality of charged particles.

7. The display panel of claim 6, wherein the electrode comprises a first electrode-portion and a second electrode-portion, the first electrode-portion is disposed at a peripheral side of a color resist unit corresponding to the privacy unit, the second electrode-portion exceeds the color resist unit, and the second electrode-portion is closer to the first surface than the first electrode-portion;
the plurality of charged particles carry charges of a first polarity, and when the first electrode-portion is loaded with a voltage signal of a second polarity and the second electrode-portion is loaded with a voltage signal of the first polarity, the plurality of charged particles are adsorbed by the first electrode-portion, and the privacy film is in the first state; and
the plurality of charged particles carry the charges of the first polarity, and when the first electrode-portion and the second electrode-portion each are loaded with the voltage signal of the second polarity, the plurality of charged particles are adsorbed by the first electrode-portion and the second electrode-portion, and the privacy film is in the second state.

8. The display panel of claim 1, wherein the carrier plate further defines a plurality of recesses corresponding to the plurality of privacy units, different recesses correspond to different privacy units, and at least part of the privacy unit is accommodated in a corresponding recess.

9. The display panel of claim 6, further comprising a signal line disposed on the carrier plate, wherein the signal line is electrically connected to the electrode and configured to load the electrical signal to the electrode.

10. A display device comprising a housing and a display panel, wherein the housing is configured to accommodate the display panel, and the display panel has a light-exiting surface and comprises:
a color film substrate comprising a carrier plate and a plurality of color resist units, wherein the carrier plate has a first surface and a second surface opposite to the first surface, the first surface is closer to the light-exiting surface than the second surface, and the plurality of color resist units are arranged at intervals on the carrier plate and are away from the first surface; and
a privacy film comprising a plurality of privacy units, wherein the plurality of privacy units are disposed corresponding to the plurality of color resist units, different privacy units correspond to different color resist units, each of the plurality of privacy units has a transparent film and a plurality of charged particles, the transparent film covers a corresponding color resist unit and part of the transparent film is located in at least part of a gap between two adjacent color resist units, the transparent film defines a cavity, and the plurality of charged particles are accommodated in the cavity; wherein
the privacy film has a first state and a second state, and when the privacy film is in the first state, the plurality of charged particles in the privacy unit are attached to one end of the transparent film close to the corresponding color resist unit and exceed a surface of the corresponding color resist unit by a first height; when the privacy film is in the second state, the plurality of charged particles in the privacy unit are attached to said one end of the transparent film close to the corresponding color resist unit and exceed the surface of the corresponding color resist unit by a second height, and the second height is greater than the first height; and when the privacy film is in the first state or the second state, at least part of each of the plurality of charged particles is disposed in the gap between the two adjacent color resist units.

11. The display device of claim 10, wherein the transparent film comprises a first film-portion and a second film-portion, the first film-portion is attached to a surface of the corresponding color resist unit close to the light-exiting surface, the second film-portion and a peripheral edge of the first film-portion are connected in a bent manner and cooperatively define the cavity, and the second film-portion is farther away from the corresponding color resist unit than the first film-portion.

12. The display device of claim 10, wherein the gap is defined between the two adjacent color resist units, and a transparent film in one of two adjacent privacy units is located in part of the gap; and a transparent film in the other one of the two adjacent privacy units is located in the other part of the gap and abuts against the transparent film in said one of the two adjacent privacy units.

13. The display device of claim 12, wherein the plurality of charged particles are filled in the gap, the gap has a first orthographic projection on the light-exiting surface, the plurality of charged particles have a second orthographic projection on the light-exiting surface, and the second orthographic projection at least partially covers the first orthographic projection.

14. The display device of claim 13, wherein the two adjacent color resist units each have a third orthographic projection on the light-exiting surface, and the third orthographic projection abuts against the second orthographic projection, but overlaps no second orthographic projection.

15. The display device of claim 10, wherein the privacy unit further comprises an electrode disposed at one side of the transparent film away from the cavity, and when the electrode is loaded with an electrical signal, the electrode adsorbs the plurality of charged particles.

16. The display device of claim 15, wherein the electrode comprises a first electrode-portion and a second electrode-portion, the first electrode-portion is disposed at a peripheral side of a color resist unit corresponding to the privacy unit, the second electrode-portion exceeds the color resist unit, and the second electrode-portion is closer to the first surface than the first electrode-portion;
the plurality of charged particles carry charges of a first polarity, and when the first electrode-portion is loaded with a voltage signal of a second polarity and the second electrode-portion is loaded with a voltage signal of the first polarity, the plurality of charged particles are adsorbed by the first electrode-portion, and the privacy film is in the first state; and
the plurality of charged particles carry the charges of the first polarity, and when the first electrode-portion and the second electrode-portion each are loaded with the voltage signal of the second polarity, the plurality of charged particles are adsorbed by the first electrode-portion and the second electrode-portion, and the privacy film is in the second state.

17. The display device of claim 10, wherein the carrier plate further defines a plurality of recesses corresponding to the plurality of privacy units, different recesses correspond to different privacy units, and at least part of the privacy unit is accommodated in a corresponding recess.

18. The display device of claim 15, wherein the display panel further comprises a signal line disposed on the carrier plate, wherein the signal line is electrically connected to the electrode and configured to load the electrical signal to the electrode.
